(19) United States
(12) Patent Application Publication
(10) Pub. No.: US 2020/0219749 A1
(43) Pub. Date: Jul. 9, 2020

(54) ELECTROSTATIC CHUCK AND PLASMA PROCESSING DEVICE HAVING THE SAME

(71) Applicant: XIA TAI XIN SEMICONDUCTOR (QING DAO) LTD., Qingdao (CN)

(72) Inventor: HWANKYU LEE, Singapore (SG)

(21) Appl. No.: 16/686,425

(22) Filed: Nov. 18, 2019

Related U.S. Application Data
(60) Provisional application No. 62/784,333, filed on Dec. 21, 2018.

(51) Int. Cl. H01L 21/683; H01L 21/67; H01J 37/32

(52) U.S. Cl. CPC H01L 21/6833; H01J 2237/334; H01J 37/32715; H01L 21/67069

(57) ABSTRACT

An electrostatic chuck able to compensate for different etching rates across a wafer of semiconductor material includes a chuck body, an isolation ring, a power splitter, and a bias radio frequency (RF) power source. The isolation ring penetrates through the chuck body, and divides the chuck body into two chuck regions. The two chuck regions are at inner and outer sides of the isolation ring and are insulated from each other. The bias RF power source is connected to the two chuck regions through the power splitter. The bias RF power source provides RF power to each chuck region individually according to a ratio dividing the total RF power. A plasma processing device including the electrostatic chuck is also provided.

### FIELD

The subject matter herein generally relates to semiconductor manufacture, and more particularly, to an electrostatic chuck and a plasma processing device having the electrostatic chuck.

### BACKGROUND

Plasma processing devices are used for etching semiconductor wafers. The plasma processing device may include a processing chamber, and an electrostatic chuck (ESC), an upper electrode, and a lower electrode received in the processor. The electrostatic chuck supports and holds the semiconductor wafer. When high frequency power is applied to the upper electrode or the lower electrode, plasma is generated in the processing chamber. The plasma can move toward and etch the semiconductor wafer.

However, during the etching process, the plasma may be unevenly distributed across the semiconductor wafer. That is, the plasma at different areas of the semiconductor wafer may have different densities and concentrations, and different areas of the semiconductor wafer may be etched by the plasma at different etching rates (the etching rate is defined as an etching depth into the semiconductor wafer per unit time), resulting in a poor etching uniformity. For example, the etching rate at the central area of the semiconductor wafer may be greater than the etching rate at the peripheral area. Thus, the quality of the semiconductor is not optimal.

### BRIEF DESCRIPTION OF THE DRAWINGS

Implementations of the present disclosure will now be described, by way of embodiments, with reference to the attached figures.

FIG. 1 is a cross-sectional view of an electrostatic chuck in accordance with an implementation of the present disclosure.

FIG. 2 is a top view of the electrostatic chuck of FIG. 1.

FIG. 3 is a schematic view of a plasma processing device including the electrostatic chuck of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

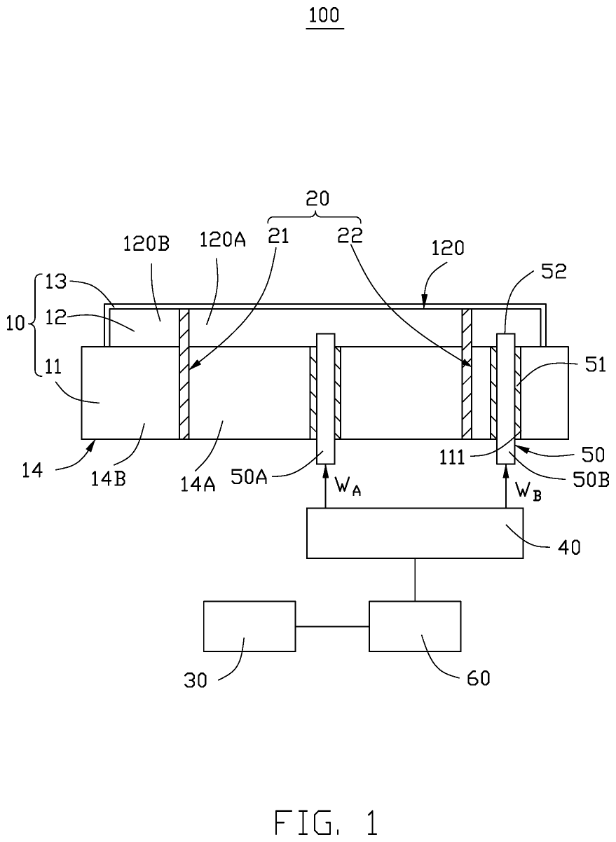

FIG. 1 illustrates a cross-sectional view of an electrostatic chuck 100 in accordance with an implementation of the present disclosure. The electrostatic chuck 100 includes a chuck body 10, an isolation ring 20, a power splitter 40, and a bias radio frequency (RF) power source 30. The isolation ring 20 penetrates through the chuck body 10, and divides the chuck body 10 into two chuck regions 14. The two chuck regions 14 are positioned at an inner side and an outer side of the isolation ring 20, and are insulated from each other. The bias RF power source 30 may be connected to the two chuck regions 14 through the power splitter 40, and provides RF power to each chuck region 14 through the power splitter 40. The isolation ring 20 is made of an insulation material, such as poly tetra fluoroethylene (PTEF).

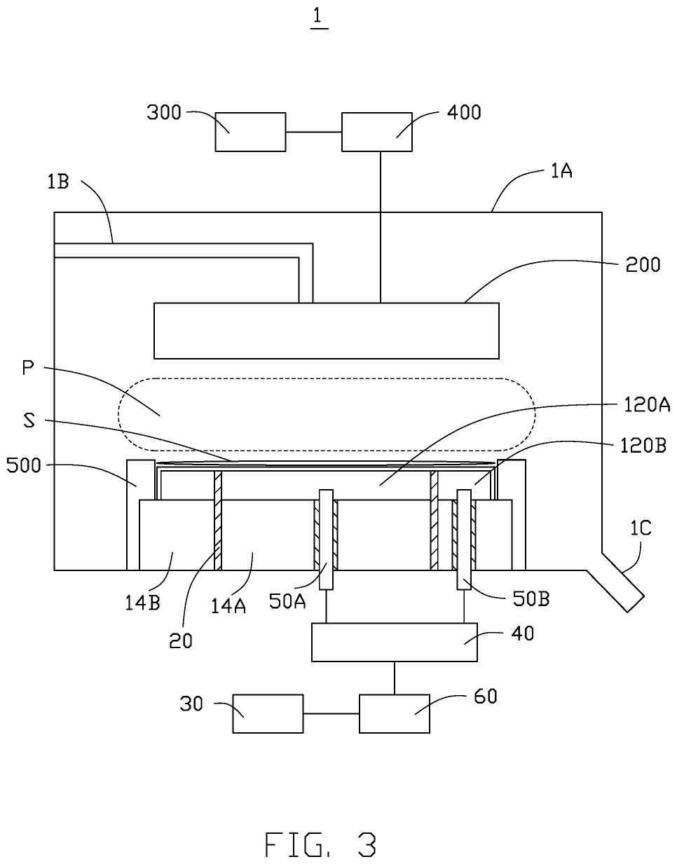

Since the bias RF power source 30 can provide the RF power to each chuck region 14 individually, the density of the plasma P (as shown in FIG. 3) on each chuck region 14 can be individually controlled. Therefore, different areas of the semiconductor wafer S (as shown in FIG. 3) held on the electrostatic chuck 100 may be uniformly etched to improve the quality of the semiconductor wafer S.

In at least one embodiment, the electrostatic chuck 100 further comprises a first power converter 60 connected between the bias RF power source 30 and the power splitter 40. The first power converter 60 may convert an original total RF power generated from the bias RF power source 30 to an actual total RF power. The power splitter 40 may split the actual total RF power to provide the respective RF power to each chuck region 14.

In at least one embodiment, the power splitter 40 may adjust a ratio of the RF power between the two chuck regions 14 when splitting the actual total RF power. That is, the power splitter 40 may adjust a ratio of the RF power for each chuck region 14 in relation to the actual total RF power. For example, when it is required to increase the etching rate at the peripheral area of the semiconductor wafer S or to decrease the etching rate at the central area of the semiconductor wafer S, the power splitter 40 can increase the ratio of the RF power for the peripheral chuck region 14 or decrease the ratio of the RF power for the central chuck region 14 in relation to the actual total RF power. On the other hand, when it is required to decrease the etching rate at the peripheral area of the semiconductor wafer S or to increase the etching rate at the central area of the semiconductor wafer S, the power splitter 40 can decrease the ratio of the RF power for the peripheral chuck region 14 or increase the ratio of the RF power for the central chuck region 14 in relation to the actual total RF power.

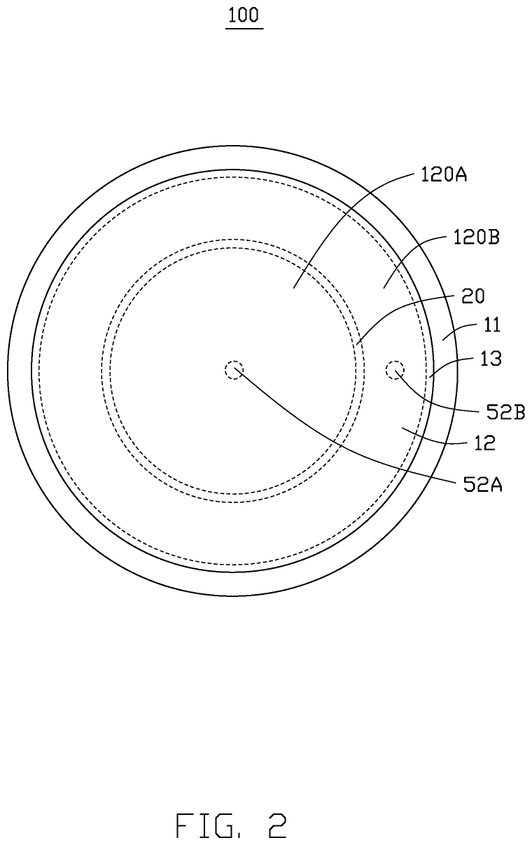

FIG. 2 illustrates a top view of the electrostatic chuck 100 of FIG. 1. The electrostatic chuck 100 includes one isolation ring 20, which divides the chuck body 10 into two chuck regions 14, namely, a first chuck region 14A and a second chuck region 14B (shown in FIG. 1). The first chuck region 14A is positioned at the inner side of the isolation ring 20 and at the central area of the semiconductor wafer S. The second chuck region 14B is positioned at the outer side of the isolation ring 20 and at the peripheral area of the semiconductor wafer S. The second chuck region 14B surrounds the first chuck region 14A. The central area and the peripheral area of the semiconductor wafer S may have same etching rates by adjusting the ratio of the RF power between the first and second chuck regions 14A and 14B.

In other embodiments, the electrostatic chuck 100 may have more isolation rings and chuck regions. For example, the electrostatic chuck includes two isolation rings, which divide the chuck body into three chuck regions. The three chuck regions may be arranged so as to be radially distinct on the semiconductor wafer S.

In at least one embodiment, the chuck body 10 includes a conductive base 11 and a conductive layer 12 formed on the conductive base 11. The isolation ring 20 penetrates through the conductive base 11 and the conductive layer 12 so as to divide the conductive layer 12 into at least two conductive portions 120. Each of the conductive portions 120 is positioned in one chuck region 14. The bias RF power source 30 provides the RF power through the power splitter 40 to each conductive portion 120 individually. The conductive base 11 and the conductive layer 12 may be made of a metal, such as aluminum. For example, when two chuck regions are formed (that is, the first chuck region 14A and the second chuck region 14B), the conductive layer 12 is thereby divided into two conductive portions, namely, a first conductive portion 120A and a second conductive portion 120B. The first conductive portion 120A and the second conductive portion 120B are respectively positioned in the first chuck region 14A and the second chuck region 14B.

The conductive layer 12 may serve as a bias electrode of the electrostatic chuck 100. When the RF power is provided to each conductive portion 120, a bias voltage is generated in each conductive portion 120, namely, bias voltages are generated in the first conductive portion 120A and the second conductive portion 120B. By managing the bias voltages, the respective densities of the plasma P on the first conductive portion 120A and the second conductive portion 120B are controlled. In at least one embodiment, a ratio of a top surface area of the first conductive portion 120A to a top surface area of the second conductive portion 120B is 4:1.

In this embodiment, the power splitter 40 may adjust a ratio of the RF power for each conductive portion 120 (e.g., the first conductive portion 120A and the second conductive portion 120B) in relation to the actual total RF power. For example, when it is required to increase the etching rate at the peripheral area of the semiconductor wafer S or to decrease the etching rate at the central area of the semiconductor wafer S, the power splitter 40 can increase the ratio by applying W_{B}/W_{A}, wherein W_{B} denotes the RF power for the second conductive portion 120B, and the W_{A} denotes the RF power for the first conductive portion 120A. That is, the power splitter 40 increases the ratio W_{B}/(W_{A}+W_{B}), which means a ratio of W_{B} in relation to the actual total RF power (W_{A}+W_{B}). On the other hand, when it is required to decrease the etching rate at the peripheral area of the semiconductor wafer S or to increase the etching rate at the central area of the semiconductor wafer S, the power splitter 40 can decrease the ratio by W_{B}/W_{A}. That is, the power splitter 40 decreases the ratio of W_{B} in relation to the actual total RF power (W_{A}+W_{B}).

In at least one embodiment, the electrostatic chuck 100 further includes a first isolation layer 13 covering the conductive layer 12. That is, the first isolation layer 13 covers lateral surfaces and a top surface of the conductive layer 12. An electrostatic electrode (not shown) is embedded in the first isolation layer 13. When a DC voltage is applied to the electrostatic electrode, opposite charges are generated at the electrostatic chuck 100 and the semiconductor wafer S. Accordingly, the semiconductor wafer S is attracted to and held on the electrostatic chuck 100 under the electrostatic force. The first isolation layer 13 may be made of an insulation material, such as ceramic. The first isolation layer 13 may be formed by plasma spraying, thermal deposition, or sputtering.

In at least one embodiment, the electrostatic chuck 100 further includes at least two conductive pins 50 connected to the at least two conductive portions 120. At least two through holes 111 penetrate the conductive base 11 for accommodating the at least two conductive pins 50. For example, a first conductive pin 50A and a second conductive pin 50B are configured for the first chuck region 14A and the second chuck region 14B, respectively. The bias RF power source 30 is connected to each conductive pin 50 through the power splitter 40 to provide the respective RF power to each conductive portion 120. The conductive pins 50 may be made of a metal, such as copper.

One end 52 of each conductive pin 50 is embedded in and electrically connected to one conductive portion 120 to serve as a conductive terminal. In this embodiment, the end 52 of the first conductive pin 50A is electrically connected to the first conductive portion 120A. The end 52 of the second conductive pin 50B is electrically connected to the second conductive portion 120B.

In at least one embodiment, the conductive base 11 further includes at least two second isolation layers 51 on inner sidewalls of the at least two through holes 111. Each second isolation layer 51 surrounds a corresponding one conductive pin 50. The conductive pins 50 are electrically insulated from the conductive base 11 by the second isolation layers 51. The second isolation layers 51 is made of an insulation material, such as PTEF.

In at least one embodiment, a width of the isolation ring 20 is in the range of 0.1 centimeter to 0.8 centimeter. That is, the isolation ring 20 includes an inner surface 21 and an outer surface 22 opposite to the inner surface 21, and the distance between the inner surface 21 and the outer surface 22 is in the range of 0.1 to 0.8 centimeters. When the width is greater than 0.8 centimeter, the electrostatic force generated between the electrostatic chuck 100 and the semiconductor wafer S is not large enough to stably hold the semiconductor wafer S. When the width is less than 0.1 centimeter, the two chuck regions 14 cannot be insulated from each other by the isolation ring 20.

FIG. 3 illustrates a schematic view of a plasma processing device 1 having the electrostatic chuck 100 and a processing chamber 1A in accordance with an implementation of the present disclosure. The electrostatic chuck 100 is installed in the processing chamber 1A.

In at least one embodiment, the plasma processing device 1 further includes an upper electrode 200, a lower electrode (not shown), and a high frequency power source 300. The upper electrode 200 and the lower electrode are also installed in the processing chamber 1A. The electrostatic chuck 100 is positioned between the upper electrode 200 and the lower electrode. The processing chamber 1A includes a gas channel 1B connected to the upper electrode 200. Gas for the process (processing gas) may be supplied to the upper electrode 200 through the gas channel 1B. The upper electrode 200 may serve as a shower head to spray the processing gas into the processing chamber 1A. The high frequency power source 300 is connected to the upper electrode 200 or the lower electrode. The high frequency power source 300 may provide high frequency power to the upper electrode 200 or the lower electrode, thereby ionizing the processing gas and generating the plasma P between the upper electrode 200 and the lower electrode.

The processing chamber 1A may further include an outlet 1C near the bottom of the processing chamber 1A. The waste gas generated during the etching process can be discharged from the processing chamber lA through the outlet 1C.

In at least one embodiment, the high frequency power source 300 is connected to the upper electrode 200. The plasma processing device 1 further includes a second power converter 400 connected between the high frequency power source 300 and the upper electrode 200. The second power converter 400 may convert an original total high frequency power generated from the high frequency power source 300 to the high frequency power.

In at least one embodiment, the plasma processing device 1 further includes an edge ring 500 surrounding the electrostatic chuck 100. When the semiconductor wafer S is held on the electrostatic chuck 100, the edge ring 500 also surrounds the semiconductor wafer S. The edge ring 500 protects the semiconductor wafer S and prevents the semiconductor wafer S from being etched by the plasma P.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. An electrostatic chuck, comprising:
a chuck body;
an isolation ring penetrating through the chuck body, the isolation ring dividing the chuck body into two chuck regions, wherein the two chuck regions are respectively positioned at an inner side and an outer side of the isolation ring and insulated from each other;
a power splitter; and
a bias radio frequency (RF) power source connected to each of the two chuck regions through the power splitter, wherein the bias RF power source provides RF power to each of the chuck regions individually through the power splitter.

2. The electrostatic chuck of claim 1, wherein the chuck body comprises a conductive base and a conductive layer formed on the conductive base, the isolation ring penetrates through the conductive base and the conductive layer so as to divide the conductive layer into at least two conductive portions.

3. The electrostatic chuck of claim 2, wherein the chuck body further comprises a first isolation layer covering the conductive layer.

4. The electrostatic chuck of claim 2, further comprising:
at least two conductive pins connected to the at least two conductive portions; and at least two through holes penetrating the conductive base for accommodating each of the at least two conductive pins, wherein the bias RF power source is connected to each of the conductive pins through the power splitter to provide respective RF power to each of the conductive portions.

5. The electrostatic chuck of claim 4, wherein the conductive base comprises at least two second isolation layers on inner sidewalls of the at least two through holes, the at least two conductive pins are electrically insulated from the conductive base by the at least two second isolation layers.

6. The electrostatic chuck of claim 4, wherein one end of each of the conductive pins is electrically connected to a corresponding one of the conductive portions to serve as a conductive terminal.

7. The electrostatic chuck of claim 2, further comprising a power converter connected between the bias RF power source and the power splitter, wherein the power converter is configured to convert an original total RF power generated from the bias RF power source to an actual total RF power, and the power splitter is configured to split the actual total RF power to provide respective RF power to each of the conductive portions.

8. The electrostatic chuck of claim 1, wherein the chuck body comprises a conductive base and a conductive layer formed on the conductive base, the isolation ring divides the conductive layer into a first conductive portion at the inner side of the isolation ring and a second conductive portion at the outer side of the isolation ring, and a ratio of a top surface area of the first conductive portion to a top surface area of the second conductive portion is 4:1.

9. The electrostatic chuck of claim 1, wherein a width of the isolation ring is in the range of 0.1 centimeter to 0.8 centimeter.

10. A plasma processing device comprising:
a processing chamber; and
an electrostatic chuck installed in the processing chamber, the electrostatic chuck including:
a chuck body;
an isolation ring penetrating through the chuck body, the isolation ring dividing the chuck body into two chuck regions, wherein the two chuck regions are respectively positioned at an inner side and an outer side of the isolation ring and insulated from each other;
a power splitter; and
a bias radio frequency (RF) power source connected to each of the two chuck regions through the power splitter, wherein the bias RF power source provides RF power to each of the two chuck regions individually through the power splitter.

11. The plasma processing device of claim 10, wherein the chuck body comprises a conductive base and a conductive layer formed on the conductive base, the isolation ring penetrates through the conductive base and the conductive layer so as to divide the conductive layer into at least two conductive portions.

12. The plasma processing device of claim 11, wherein the chuck body further comprises a first isolation layer covering the conductive layer.

13. The plasma processing device of claim 11, wherein the electrostatic chuck further comprises:
at least two conductive pins connected to the at least two conductive portions; and
at least two through holes penetrating the conductive base for accommodating each of the at least two conductive pins, wherein the bias RF power source is connected to each of the conductive pins through the power splitter to provide respective RF power to each of the conductive portions.

14. The plasma processing device of claim 13, wherein the conductive base comprises at least two second isolation layers on inner sidewalls of the at least two through holes, the at least two conductive pins are electrically insulated from the conductive base by the at least two second isolation layers.

15. The plasma processing device of claim 11, wherein the electrostatic chuck further comprises a power converter connected between the bias RF power source and the power splitter, the power converter is configured to convert an original total RF power generated from the bias RF power source to an actual total RF power, and the power splitter is configured to split the actual total RF power to provide respective RF power to each of the conductive portions.

16. The plasma processing device of claim 11, wherein one end of each of the conductive pins is electrically connected to a corresponding one of the conductive portions to serve as a conductive terminal.

17. The plasma processing device of claim 10, wherein the chuck body comprises a conductive base and a conductive layer formed on the conductive base, the isolation ring divides the conductive layer into a first conductive portion at the inner side of the isolation ring and a second conductive portion at the outer side of the isolation ring, and a ratio of a top surface area of the first conductive portion to a top surface area of the second conductive portion is 4:1.

18. The plasma processing device of claim 10, wherein a width of the isolation ring is in the range of 0.1 centimeter to 0.8 centimeter.

19. The plasma processing device of claim 10, further comprising:
an upper electrode;
a lower electrode, wherein the electrostatic chuck is positioned between the upper electrode and the lower electrode; and
a high frequency power source connected to the upper electrode or the lower electrode, the high frequency power source configured to provide high frequency power to the upper electrode or the lower electrode for generating plasma between the upper electrode and the lower electrode, wherein the RF power of each chuck region is configured to control a density of the plasma above each chuck region.

20. The plasma processing device of claim 10, further comprising an edge ring surrounding the electrostatic chuck.
